(19) United States
(12) Patent Application Publication
(10) Pub. No.: US 2011/0165366 A1
(43) Pub. Date: Jul. 7, 2011

(54) ELECTRONIC DEVICE AND METHOD OF FORMING THE SAME

(76) Inventors: Guowen Wang, Shenzhen (CN); Jiali Deng, Shenzhen (CN); Junjie Yuan, Shenzhen (CN); Mingyu Li, Shenzhen (CN); Dou Li, Shenzhen (CN)

(21) Appl. No.: 13/062,101

(22) PCT Filed: Sep. 23, 2009
(86) PCT No.: PCT/CN2009/074165

§ 371 Date: Mar. 3, 2011

(30) Foreign Application Priority Data
Sep. 25, 2008 (CN) 200810216557.3

(51) Int. Cl. B32B 15/04; B29C 45/00; B32B 37/02; B32B 37/06; B32B 37/10; B32B 37/12; B32B 37/14; H05K 13/00

(52) U.S. Cl. 428/68; 156/242; 156/60

(57) ABSTRACT

A method of forming an electronic device having a metal piece and a plastic piece adhered to the metal piece is provided. The method includes the step of forming an adhering part on a surface of the metal piece which at least partially covers the surface thereof. The method also includes the step of forming the plastic piece by injection molding using a plastic material which is adhered to the metal piece with the adhering part connecting the plastic piece and the metal piece.

### CROSS-REFERENCE TO RELATED APPLICATION

This application claims priority and benefit to Chinese Patent Application No. 200810216557.3, filed Sep. 25, 2008.

### FIELD OF THE INVENTION

The present invention relates to the field of electronic device, especially to an improvement of an electronic device and a method of forming the same.

### BACKGROUND OF THE INVENTION

Electronic device needs an excellent design as well as acceptable quality. It becomes more and more light and thin whereas apt to be fractured. Therefore, material with high strength and moderate plasticity is selected to manufacture the electronic devices. And if the structure of material is not strong enough, metal pieces are usually used to enhance the strength, such as insert molding with metal pieces or assembly metal pieces.

For the inlaying of large-area metal, it often needs special processes for slotting or buckling. The processes are complicated, and their yield rate is low. These cause a high cost. Moreover, because of the small bonding force between metal and plastic, there are too many limitations to design and material selection.

The method of prior art is Metal Adhesion Molding (MAM). The metal pieces are taken in mold and molded with the plastic directly. This method need no buckling or other processing and has no more demands on the metal, which is simple and could reduce the production cost. But because of no buckling, the bonding force between metal surface and the plastic surface is not strong enough. Even if the metal is processed with texture, the result of dropping and pulling test are not satisfying. If a part of the metal piece is embedded into the plastic to enhance the bonding force, the structure of metal will be complicated, and the shape of electronic device will be hard to design.

### SUMMARY OF THE INVENTION

In viewing thereof, the present invention is directed to solve at least one of the problems existing in the prior art. Accordingly, a method of forming an electronic device having a metal piece and a plastic piece adhered to the metal piece is needed, which may enhance the bonding force between the metal piece and the plastic piece with low cost. Accordingly, an electronic device manufactured therefrom is also needed.

According to an embodiment of the present invention, a method of forming an electronic device having a metal piece and a plastic piece adhered to the metal piece is provided. The method may comprise the steps of: forming an adhering part on a surface of the metal piece which at least partially covers the surface thereof; and

forming the plastic piece by injection molding using plastic material which is adhered to the metal piece with the adhering part being connected between the plastic piece and the metal piece.

According to another embodiment of the present invention, a method of forming an electronic device having a metal piece and a plastic piece adhered to the metal piece is provided, comprising the following steps: forming a texture on a surface of the metal piece; preheating the metal piece; forming an adhering part on the surface of the metal piece where the texture is formed, which at least partially covers the surface thereof; and forming the plastic piece by injection molding using plastic material which is attached to the metal piece with the adhering part being connected between the plastic piece and the metal piece.

According to still another embodiment of the invention, an electronic device formed by the method mentioned above is provided accordingly.

### BRIEF DESCRIPTION OF THE DRAWINGS

These and other aspects and advantages of the invention will become apparent and more readily appreciated from the following descriptions taken in conjunction with the drawings in which:

FIG. 1 is a partial cross-sectional view of an electronic device during molding according to an embodiment of the present invention.

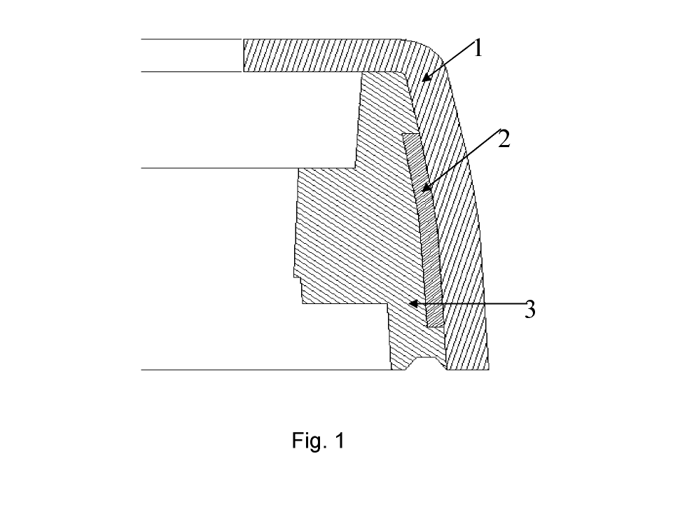

### DETAILED DESCRIPTION OF EMBODIMENTS

Reference will be made in detail to embodiments of the present invention. The embodiments described herein with reference to drawings are explanatory, illustrative, and used to generally understand the present invention. The embodiments shall not be construed to limit the present invention. The same or similar elements and the elements having same or similar functions are denoted by like reference numerals throughout the descriptions.

According to an embodiment of the invention, a method of forming an electronic device having a metal piece 1 and a plastic piece 3 adhered to the metal piece 1 is provided. The method may comprise the steps of: adhering part on a surface of the metal piece 1 which at least partially covers the surface thereof; and forming the plastic piece 3 by injection molding using plastic material which is adhered to the metal piece 1 with the adhering part being connected between the plastic piece 3 and the metal piece 1.

According to an embodiment of the invention, the metal piece 1 may be configured as a metal shell for the electronic device.

The types of plastic piece 3 may include, without limitation to, polycarbonate (PC), polymethylmethacrylate (PMMA), or mixture thereof. The weight average molecular weight of PC was about 20000-60000, and the weight average molecular weight of PMMA was about 20000-200000.

The types of metal piece 1 may include, without limitation to, iron, aluminum, aluminum alloy, copper, and stainless steel. The structure of the metal piece is designed according the device.

The adhering part 2 is used to attach the metal piece 1 to the plastic piece 3. The thickness of the adhering part is determined by the dimension of the device. In an embodiment of the invention, it is about 0.10-0.15 mm. In one example, the adhering part is formed by thermoplastic adhesive. The thermoplastic adhesive is a no solvent solid meltable polymer without any water component. It is presented in a solid state at room temperature, and it may be transformed into a viscous liquid while heating at a given temperature. In some embodiments, the thermoplastic adhesive comprises base-resin, tackifier, viscosity modifier and antioxidant. To avoid the over-melt of adhesive spilled while molding, the thermoplastic adhesive has a certain thermal resistance. According to an embodiment of the invention, the thermal resistant temperature of thermoplastic adhesive is more than 220° C.

The process of forming an adhering part 2 on the surface of metal pieces 1 is not limited in the present invention. In some embodiments, the metal piece 1 is preheated to the temperature of about 100° C.-150° C., then the thermoplastic adhesive is laminated to the metal piece by a laminated roller so that the thermoplastic adhesive on the surface of metal piece is molten and bonded on the metal piece firmly. The laminating time is about 3-7 seconds. According to an embodiment of the invention, it is about 6 seconds.

The injection process of injection molding is not limited in the present invention. In some embodiments, the metal piece 1 is put into the mold and the plastic material is injected then. In one example, the high temperature and high pressure injection molding is used to enhance the bonding force therebetween during which the high temperature is favorable for melting, and the high pressure is favorable for bonding. The temperature may be about 250° C.-300° C. and the pressure may be about 1250-1350 kg/cm².

In some embodiments, the method further comprises forming texture on the surface of metal piece 1. The process of texture is not limited in the present invention, it aims to increase the roughness and enhance bonding force.

The following provides additional details of the method of the present invention.

### First Embodiment

An aluminum alloy plate piece having a size of 100×200×2 mm and a plastic piece are molded as following:

A texture on a surface of aluminum alloy plate is formed. After the aluminum alloy plate is preheated to a temperature of 120° C., the thermoplastic adhesive (615ST/3M Co.) having a thickness of 0.12 mm is laminated on the aluminum alloy plate for 6 seconds. The aluminum alloy plate is put in the mold and the plastic material is injected on the aluminum alloy plate at the temperature of 280° C. under the pressure of 1350 kg/cm². After curing, the electronic device is obtained which may be labeled as A.

### Second Embodiment

An aluminum alloy plate having a size of 50×50×2 mm and a plastic piece are molded as following:

A texture on a surface of the aluminum alloy plate is formed. After the aluminum alloy plate is preheated to a temperature of 120° C., the thermoplastic adhesive (615ST/3M Co.) having a thickness of 0.10 mm is laminated on the aluminum alloy plate for 6 seconds. The aluminum alloy plate is put into the mold and the plastic material is injected on the aluminum alloy plate at a temperature of 280° C. under a pressure of 1250 kg/cm². After curing, the electronic device is obtained which may be labeled as B.

### Third Embodiment

An aluminum alloy plate having a size of 100×100×2 mm and a plastic piece are molding as following steps:

A texture on a surface of the aluminum alloy plate is formed. After the aluminum alloy plate is preheated to a temperature of 120° C., the thermoplastic adhesive (615ST/3M Co.) having a thickness of 0.12 mm is laminated on the aluminum alloy plate for 6 seconds. The aluminum alloy plate is put into the mold and the plastic material is injected on the aluminum alloy plate at a temperature of 285° C. under a pressure of 1350 kg/cm². After curing, the electronic device is obtained which may be labeled as C.

### Fourth Embodiment

An aluminum alloy plate having a size of 100×100×2 mm and a plastic piece are molding as following:

A texture on a surface of the aluminum alloy plate is formed. After the aluminum alloy plate is preheated to a temperature of 120° C., the thermoplastic adhesive (615ST/3M Co.) having a thickness of 0.12 mm is laminated on the aluminum alloy plate for 6 seconds. The aluminum alloy plate is put into the mold and the plastic material is injected on the aluminum alloy plate at a temperature of 295° C. under a pressure of 1350 kg/cm². After curing, the electronic device is obtained which may be labeled as D.

### Comparative Embodiment

An aluminum alloy plate having a size of 100×100×2 mm and a plastic piece are molding as following steps:

The aluminum alloy plate is put into the mold and the plastic material is injected on the aluminum alloy plate at a temperature of 295° C. under a pressure of 1350 kg/cm². After curing, the electronic device is obtained which may be labeled as E.

Testing

The pulling force test machine is used to peel the metal piece and the plastic piece of the electronic devices A-E respectively, with the peeling force being shown in Table 1.

TABLE 1
PEELING FORCE OF ELECTRONIC DEVICES A-E.

| No. | Peeling Force (N) |
|---|---|
| A | 320 |
| B | 330 |
| C | 300 |
| D | 280 |
| E | 160 |

Based on the results of Table 1, the method provided by the embodiments of present invention can enhance the bonding force between the metal piece 1 and the plastic piece 3. And the service time of the electronic device is extended accordingly.

Although explanatory embodiments have been shown and described, it would be appreciated by those skilled in the art that changes, alternatives, and modifications may be made in the embodiments without departing from spirit and principles of the invention. Such changes, alternatives, and modifications all fall into the scope of the claims and their equivalents.

1. A method of forming an electronic device having a metal piece and a plastic piece adhered to the metal piece, comprising the steps of:
forming an adhering part on a surface of the metal piece which at least partially covers the surface thereof; and
forming the plastic piece by injection molding using a plastic material which is adhered to the metal piece with the adhering part connecting the plastic piece and the metal piece.

2. The method according to claim 1, wherein the metal piece includes one or more of iron, aluminum, aluminum alloy, copper, and stainless steel.

3. The method according to claim 2, wherein material of the adhering part is thermoplastic adhesive.

4. The method according to claim 3, wherein the thermoplastic adhesive has a thermal resistance temperature of greater than 220° C.

5. The method according to claim 1, further comprising: preheating the metal piece before forming the adhering part.

6. The method according to claim 5, wherein the preheating is performed under a temperature of about 100° C. to 150° C.

7. The method according to claim 1, further comprising the step of forming a texture on the surface of the metal piece.

8. The method according to claim 2, wherein the metal piece is a metal shell for the electronic device.

9. The method according to claim 1, wherein the surface of the metal piece is entirely covered by the adhering part.

10. A method of forming an electronic device having a metal piece and a plastic piece adhered to the metal piece, comprising the following steps:
forming a texture on a surface of the metal piece;
preheating the metal piece;
forming an adhering part on the surface of the metal piece where the texture is formed, which at least partially covers the surface thereof; and
forming the plastic piece by injection molding using plastic material which is attached to the metal piece with the adhering part connecting the plastic piece and the metal piece.

11. The method according to claim 10, wherein the metal piece is a metal shell for the electronic device.

12. The method according to claim 10, wherein the metal piece includes one or more of iron, aluminum, aluminum alloy, copper, and stainless steel.

13. The method according to claim 10, wherein material of the adhering part is thermoplastic adhesive.

14. The method according to claim 13, wherein the thermoplastic adhesive has a thermal resistance temperature of greater than 220° C.

15. The method according to claim 10, wherein temperature of the preheating is about 100° C. to 150° C.

16. The method according to claim 10, wherein the surface of the metal piece is entirely covered by the adhering part.

17. An electronic device formed by the method according to claim 1.

18. An electronic device formed by the method according to claim 10.

19. A method of forming a device having a metal piece and a plastic piece adhered to the metal piece, comprising:
preheating the metal piece to a predetermined temperature;
forming an adhering part on a surface of the metal piece; and
forming the plastic piece by injecting, at a predetermined pressure and a predetermined temperature, a plastic material onto the surface of the metal piece where the adhering part is formed, the plastic piece and the metal piece being bonded by the adhering part.

20. The method of claim 19, wherein the predetermined pressure for injecting the plastic material is at least 1250 kg/cm², and wherein the predetermined temperature for injecting the plastic material is at least 280° C.
